(19) United States
(12) Patent Application Publication
(10) Pub. No.: US 2015/0187513 A1
(43) Pub. Date: Jul. 2, 2015

(54) PHOTOSENSITIZERS, METHOD OF MAKING THEM AND THEIR USE IN PHOTOELECTRIC CONVERSION DEVICES

(71) Applicant: American University of Beirut, Beirut (LB)

(72) Inventors: Tarek Ghaddar, Beirut (LB); Tharallah Shoker, Beirut (LB)

(73) Assignee: American University of Beirut, Beirut (LB)

(21) Appl. No.: 14/141,057

(22) Filed: Dec. 26, 2013

(51) Int. Cl. H01G 9/20; H01L 51/00; C07F 15/00

(52) U.S. Cl. CPC H01G 9/2059; C07F 15/0046; H01L 51/0086; C07F 15/0053

(57) ABSTRACT

Disclosed are novel photosensitizers, method of making them, and their use in photoelectric conversion devices such as the Dye Sensitized Solar Cell (DSSC). The photosensitizers have the Formula M(L1)₂L2L3, M(L1)₃L4 and ML4L5 where L1, (L2-L3) and (L4-L5) represent independently monodentate, bidentate and tridentate ligands of specific structures, respectively.

### BACKGROUND

In the past two decades high interest in the dye sensitized solar cell (DSSC) research area has been immense due the potential for commercialization [1]. Recently, DSSC's efficiencies of 12.3% have been attained using a zinc-porphyrin complex as a sensitizer along with a liquid electrolyte system, and efficiencies of 15% for perovskite-based solid state DSSC's [2, 3]. Currently, dyes known as very efficient sensitizers in liquid based or semi-solid based DSSC include the N3 dye (N719 when in the di-anionic form) [Ru(NCS)₂(dcbpy)₂] where dcbpy is 4,4′-dicarboxy-2,2′bipyridine [4], and the black dye [Ru(NCS)₃(tctpy)] where tctpy is 4,4′,4″-tricarboxy-2,2′:6′,2″-terpyridine [5]. Recently, designing new metal based dye complexes with long-term chemical stability is of great interest. In addition, red-shifting the absorption band of the sensitizer in the visible and near-IR region may have positive effects on DSSCs' efficiencies.

### SUMMARY OF THE INVENTION

Within the scope of the invention, one embodiment is a designed, synthesized and applied new class of dyes in fully functional dye-sensitized solar cells. The inventive dyes overcome problems that many commercial and non-commercial dyes possess such as, but not limited to: low absorption in the near IR (which lowers the photocurrent), bad long term stability, lengthy and pricey synthesis, aggregation in solution which require additives to be used in conjunction with the dye, low solubility, and most importantly the cells suffer from accelerated electron recombination processes which in turn lowers the voltage and thus the overall efficiency. The inventive dyes are easily made from cheap chemicals with no need for high temperatures or prolonged reaction times. They are easily purified with high reaction yields. They are one of the most easily manipulated classes of dyes, where they can be prepared, using the right design, to be hydrophilic or hydrophobic, to absorb up to from 600 to 900 nm, to have a redox between 0.9 and 1.2 eV vs the normal hydrogen electrode, etc.

Most importantly, the inventive dyes do not exhibit significant acceleration in electron recombination processes when compared to the best performing commercial dye (N719). The electron lifetime and voltages are comparable to the currently best performing known dye N719. In addition, their good light absorption and panchromatic nature with near 100% efficiency of electron injection and dye regeneration, they show high currents and thus very good solar cell efficiencies.

Within the scope of the invention includes an embodiment of novel photosensitizers that have the formula M(L1)₂L2L3, where M represents a metal belonging to one of the groups 6-11 in a long-format periodic table. Preferably, M includes but is not limited to iron, ruthenium, osmium, iridium, cobalt, palladium, platinum, and chromium. More preferably, M is ruthenium.

The ligand L1 represents a monodentate ligand corresponding to Formula I:

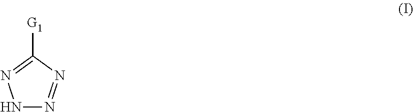

Group G1 may include, but is not limited to, the following: halogens, cyanos, alkyl groups, halogenated alkyl groups, alkoxy groups, halogenated alkoxy groups, aryl groups, halogenated aryl groups, aryloxy groups, halogenated aryloxy groups, heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, and halogenated aryl amino groups.

Ligands L2 and L3 are the same or different bidentate ligands, wherein at least one of L2 or L3 corresponds to Formula (II):

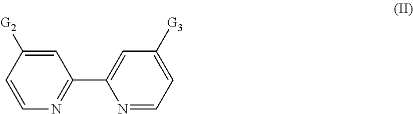

Groups G2 and G3 are the same or independently selected and may include, but are not limited to, the following: hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

Another embodiment within the scope of the invention includes a compound having the Formula M(L1)₃L4 wherein M represents a metal belonging to one of the groups 6-11 of a long-format periodic table. Preferably, M includes but is not limited to iron, ruthenium, osmium, iridium, cobalt, palladium, platinum, and chromium. More preferably, M is ruthenium.

The ligand L1 represents a monodentate ligand corresponding to Formula I. The ligand L4 corresponds to Formula (III):

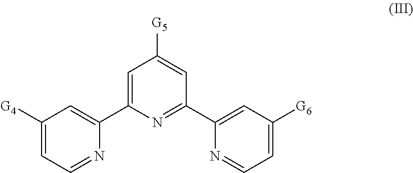

Groups G4, G5 and G6 are the same or independently selected and may include, but are not limited to, the following: hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

Another embodiment within the scope of the invention includes a compound having the Formula ML4L5, wherein M represents a metal belonging to one of the groups 6-11 of a long-format periodic table. Preferably, M includes but is not limited to iron, ruthenium, osmium, iridium, cobalt, palladium, platinum, and chromium. More preferably, M is ruthenium.

Ligand L4 represents a tridentate ligand corresponding to Formula III. Ligand L5 represents a tridentate ligand corresponding to Formula IV:

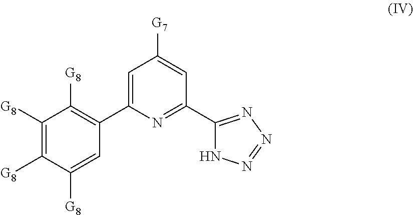

Groups G7 and G8 are independently selected and may include, but are not limited to, the following: halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups and anchoring groups.

Another embodiment within the scope of the invention includes an embodiment of novel photosensitizers wherein the compound is a salt.

Another embodiment within the scope of the invention, is the use of the compounds in a photoelectric conversion device including, but not limited to a dye-sensitized solar cell. The dye-sensitized solar cell may further be comprised of a semiconducting element.

Another embodiment within the scope of the invention is a dye-sensitized solar cell comprised of the inventive compounds individually or in combination thereof which exhibit better photoelectric conversion efficiency, better device efficiency, and longer life expectancy for DSSCs.

The methods, systems, and apparatuses are set forth in part in the description which follows, and in part will be obvious from the description, or can be learned by practice of the methods, apparatuses, and systems. The advantages of the methods, apparatuses, and systems will be realized and attained by means of the elements and combinations particularly pointed out in the appended claims. It is to be understood that both the foregoing general description and the following detailed description are exemplary and explanatory only and are not restrictive of the methods, apparatuses, and systems, as claimed.

### BRIEF DESCRIPTION OF THE DRAWINGS

In the accompanying figures, like elements are identified by like reference numerals among the several preferred embodiments of the present invention.

FIG. 1 illustrates the absorption and emission spectra of embodiments of the inventive dye.

FIG. 2 shows a cyclic voltammogram scan for T135 and T136

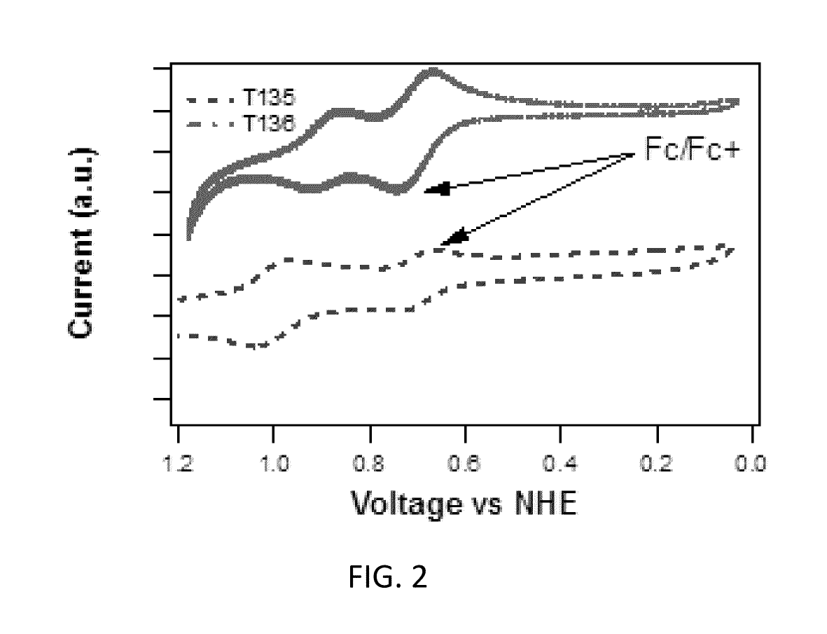

FIG. 3A shows a differential pulse voltammogram for T133, T134, and T136.

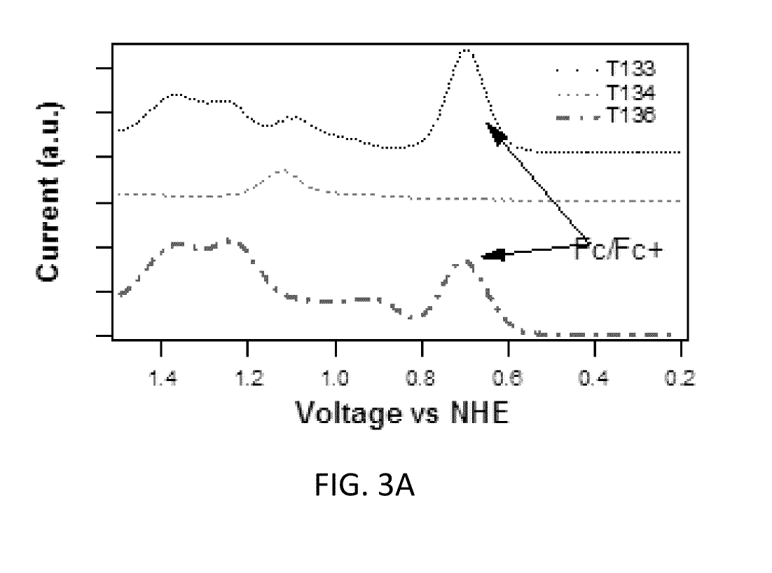

FIG. 3B shows differential pulse voltammogram for T120.

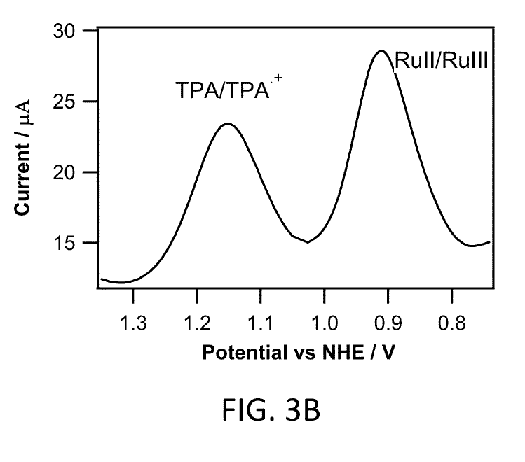

FIG. 4 compares the photocurrent voltage characteristics of DSSCs.

FIG. 5 compares the incident photon to charge carrier efficiency and integrated current spectra of embodiments of the inventive dye with N719.

FIG. 6 compares the electron lifetimes of embodiments of the inventive dye with N719.

FIG. 7 illustrates an embodiment of a DSSC.

### DETAILED DESCRIPTION OF THE INVENTION

The foregoing and other features and advantages of the invention are apparent from the following detailed description of exemplary embodiments, read in conjunction with the accompanying drawings. The detailed description and drawings are merely illustrative of the invention rather than limiting, the scope of the invention being defined by the appended claims and equivalents thereof.

Within the scope of the invention includes an embodiment of novel photosensitizers that have the formula M(L1)₂L2L3, where M represents a metal belonging to one of the groups 6-11 in a long-format periodic table. Preferably, M includes but is not limited to iron, ruthenium, osmium, iridium, cobalt, palladium, platinum, and chromium. More preferably, M is ruthenium.

The ligand L1 represents a monodentate ligand corresponding to Formula I:

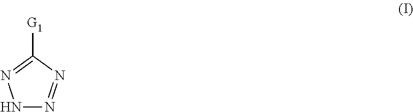

Functional group G1 may include, but is not limited to, the following: halogens, cyanos, alkyl groups, halogenated alkyl groups, alkoxy groups, halogenated alkoxy groups, aryl groups, halogenated aryl groups, aryloxy groups, halogenated aryloxy groups, heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, and halogenated aryl amino groups. For example, alkyls or halogenated alkyls may include, but are not limited to —C₆H₁₃, —CF₃, or —CF₂(CF₂)₄CF₃. Examples of aryls include structures represented by Formula (a):

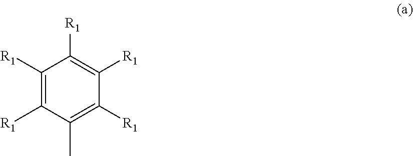

wherein R₁ of Formula (a) includes, but is not limited to, the following: hydrogen, halogen, halogenated alkyl groups, preferably —F, —CF₃, —CF₂(CF₂)₄CF₃, alkyl or alkoxy group. Preferred R₁ functional groups are alkyl or alkoxy groups. More preferred R₁ functional groups are butyl, hexyl, octyl, butoxy, hexyloxy, or octyloxy groups.

Examples of heterocycle functional groups are represented by one of the Formulas (b) to (h) listed below:

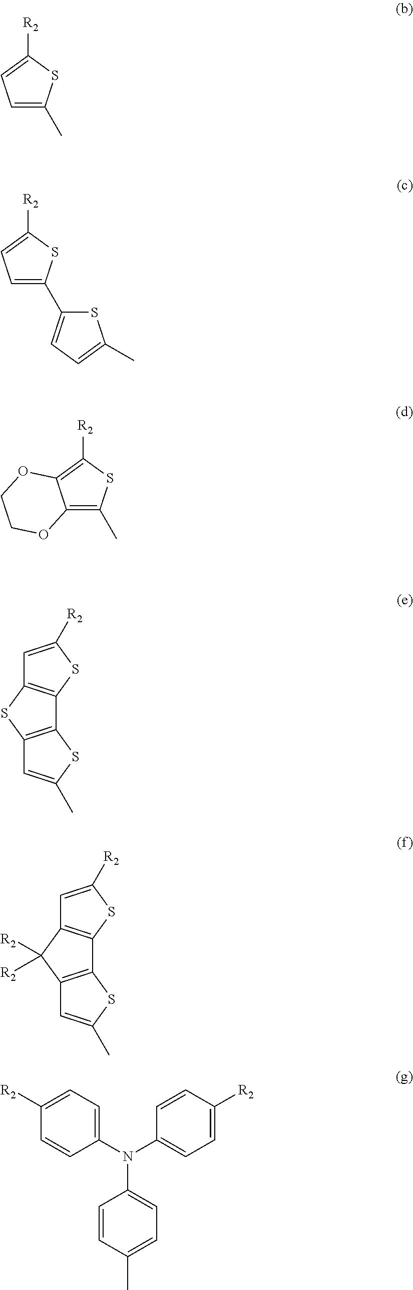

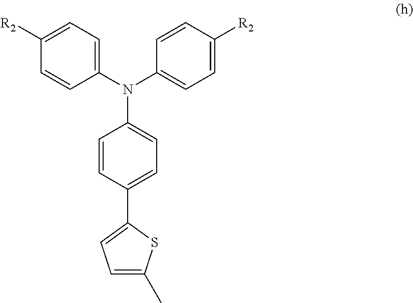

wherein R₂ of Formulas (b) to (h) includes, but is not limited to, the following: hydrogen, alkyl, thioalkyl or alkoxy groups. A preferred R₂ functional group is an alkyl. More preferred R₂ functional groups are butyl, hexyl, or octyl groups.

Ligands L2 and L3 are the same or different bidentate ligands, wherein at least one of L2 or L3 corresponds to Formula (II):

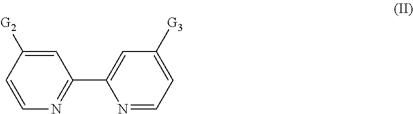

Functional groups G2 and G3 are the same or independently selected and may include, but are not limited to, the following: hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

Another embodiment within the scope of the invention includes a compound having the Formula M(L1)₃L4 wherein M represents a metal belonging to one of the groups 6-11 of a long-format periodic table. Preferably, M includes but is not limited to iron, ruthenium, osmium, iridium, cobalt, palladium, platinum, and chromium. More preferably, M is ruthenium.

The ligand L1 represents a monodentate ligand corresponding to Formula I. The ligand L4 corresponds to Formula (III):

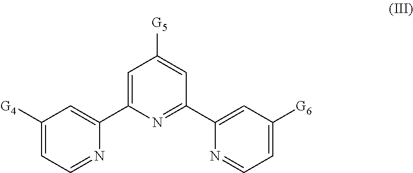

Functional groups G4, G5 and G6 are the same or independently selected and may include, but are not limited to, the following: hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

Functional groups G2, G3, G4, G5, and G6 are the same or different and are preferably hydrogen, an anchoring group, or any of the structures represented by Formulas (a) to (h).

Another embodiment within the scope of the invention includes a compound having the Formula ML4L5, wherein M represents a metal belonging to one of the groups 6-11 of a long-format periodic table. Preferably, M includes but is not limited to iron, ruthenium, osmium, iridium, cobalt, palladium, platinum, and chromium. More preferably, M is ruthenium.

Ligand L4 represents a tridentate ligand corresponding to Formula III. Ligand L5 represents a tridentate ligand corresponding to Formula IV:

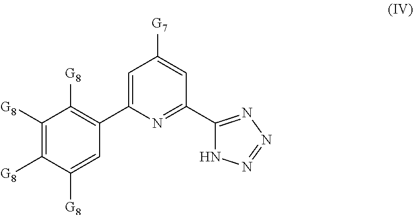

Functional groups G7 and G8 are independently selected and may include, but are not limited to, the following: halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups and anchoring groups. Preferably G7 includes, but is not limited to, the following: hydrogen, an anchoring group, or a structure represented by Formulas (a) to (h). Preferably G8 includes, but is not limited to, the following: hydrogen, halogen, and halogenated alkyl groups. More preferably, G8 includes, but is not limited to, the following: —F, —CF₃, —CF₂(CF₂)₄CF₃.

Anchoring groups within the scope of the invention include, but are not limited to, the following: —COOH, —PO₃H₂, —PO₄H₂, —SO₃H, —CONHOH, acetylacetonate, acrylic acid derivatives, malonic acid derivative, rhodanine-3-acetic acid, propionic acid, deprotonated forms of the aforementioned, salts of said deprotonated forms, and chelating groups with it-conducting character, preferably —COOH and salts of —COOH, and more preferably —COOH and ammonium or alkali metal salts of —COOH. The foregoing anchoring groups are merely exemplary. Anchoring groups are well known in the art and one of ordinary skill in the art is necessarily familiar with such anchoring groups that share the same characteristics as the examples listed. Accordingly, anchoring groups that share the same characteristics as the examples listed are within the scope of the invention.

General Synthetic Procedures

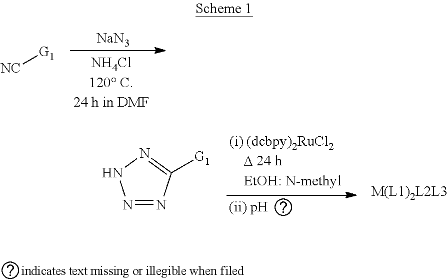

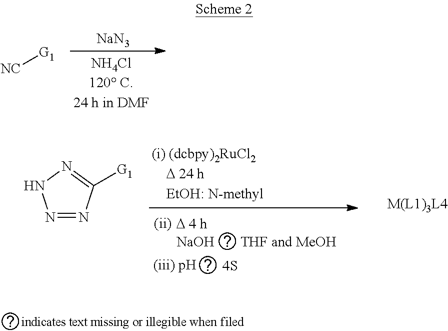

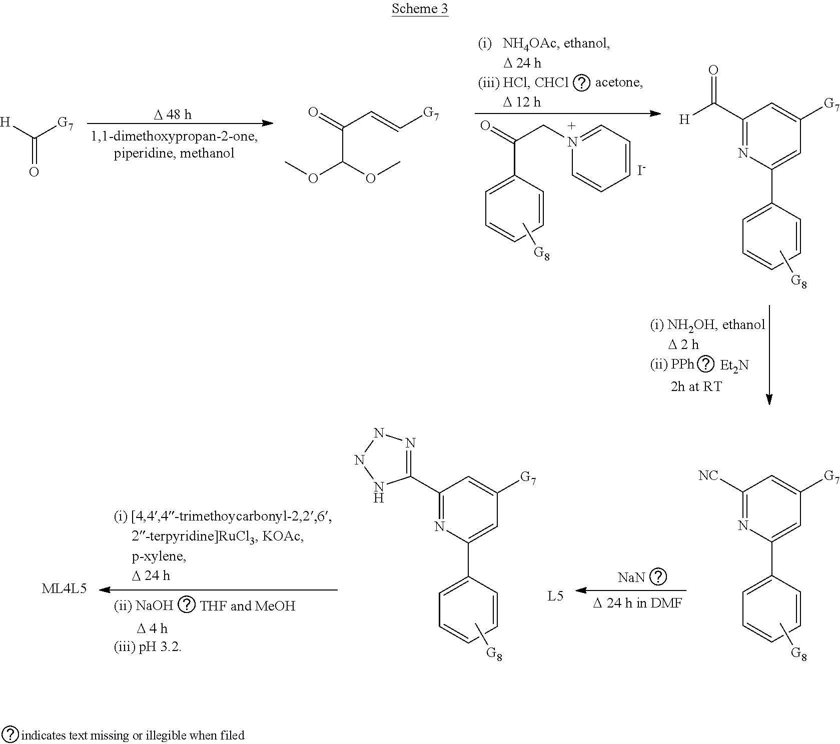

Example Ru(II) Complexes

These detailed descriptions serve to exemplify the above general synthetic schemes which form part of the invention. These detailed descriptions are presented for illustrative purposes only and are not intended as a restriction on the scope of the invention. One of ordinary skill in the art of inorganic synthesis necessarily understands that the detailed descriptions below enable synthesis of both the salt and neutral forms of the compound. All parts are by weight and temperatures are in Degrees Celsius unless otherwise indicated. All compounds showed NMR spectra consistent with their assigned structures.

### EXAMPLE 1

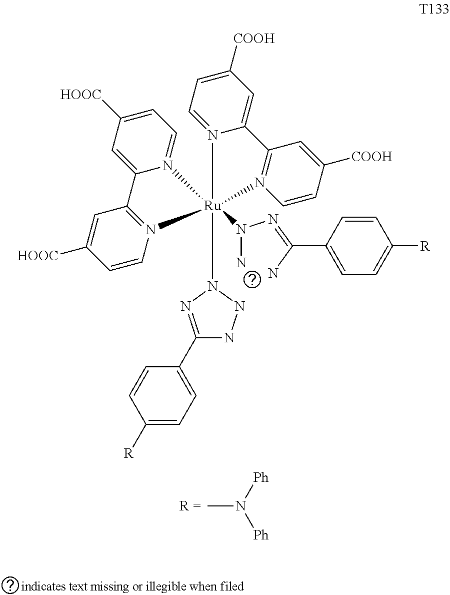

### Ru(L1)₂L2L3: T133

T133 is one example compound of the M(L1)₂L2L3 embodiment of the present invention.

### Step 1. Preparation of N,N-diphenyl-4-(2H-tetrazol-5-yl)benzenamine, (L2)

To a solution of 4-(diphenylamino)benzonitrile (1.00 g, 3.70 mmol) in DMF (100 mL) was added sodium azide (0.72 g, 11.11 mmol) and ammonium chloride (0.61 g, 11.11 mmol). The reaction mixture was stirred for 24 h at 120° C. After being cooled to room temperature, the solvent was evaporated under reduced pressure. The residue was extracted with water and ethyl acetate (30 ml×3). The organic layer was washed with brine, dried over MgSO₄, filtered and concentrated under vacuum. Purification was accomplished via silica gel column chromatography using hexane:ethyl acetate (2:1) as an eluent to afford N,N-diphenyl-4-(2H-tetrazol-5-yl)benzenamine as a pure solid (0.78 g, 68% yield). ¹H NMR (300 MHz, CDCl₃): δ 7.89-7.86 (d, J=8.4 Hz, 2H), 7.34-7.26 (m, 4H), 7.16-7.09 (m, 8H). ¹³C NMR (75 MHz, CDCl₃) 150.85, 146.61, 129.61, 128.30, 125.64, 125.15, 124.38, 121.38, 115.64. APPI MS (m/z): calculated for C₁₉H₁₄N₅ [M−H+]−, 312.1; found, 311.9.

### Step 2. Preparation of the Ruthenium Complex T133

The corresponding ligand L2 (2 eq.) and (dcbpy)₂RuCl₂ (1 eq.) were refluxed overnight under N₂ in 5:1:1 ethanol:water:N-methylmorpholine. The solvent was then taken off under vacuum and the obtained dark solid was dissolved in water containing excess tetra-butyl ammonium hydroxide (TBAOH) and applied to a preparative C18-column. The compound was purified by a gradient elution with water/methanol 100%:0% to 80%:20%. Concentrating the solvent that contains the major band under reduced pressure and acidifying to pH 4.8 with 0.1 M HNO₃ resulted in a dark precipitate. The solid was filtered to yield a dark solid, which was dried under vacuum at 60° C. for 24 h. This afforded the dye with one TBA⁻ as a counter cation with quantitative yields.

T133•TBA: ¹H NMR (300 MHz, MeOD): δ 10.07-10.05 (d, J=5.7 Hz, 2H), 8.94 (s, 2H), 8.82 (s, 2H), 8.16-8.13 (d, J=6.1 Hz, 2H), 8.07-8.05 (d, J=6.1 Hz, 2H), 7.74-7.64 (m, 6H), 7.3-7.24 (m, 8H), 7.06-6.95 (m, 16H), 3.22-3.16 (m, 8H), 1.67-1.56 (m, 8H), 1.43-1.28 (m, 8H), 1.00-0.95 (t, J=7.2 Hz, 12H). APPI MS (m/z): calculated for C₇₈H₇₉N₁₅O₈Ru [M−H+]−, 1454.5; found, 1453.7.

### EXAMPLE 2

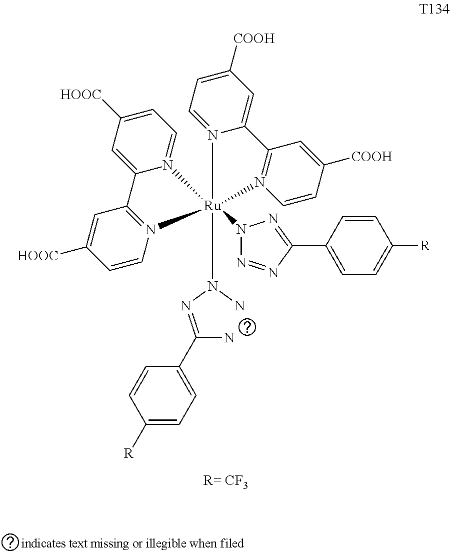

### Ru(L1)₂L2L3: T134

T134 is another example compound of the M(L1)₂L2L3 embodiment of the present invention.

### Step 1. Preparation of 5-(4-(trifluoromethyl)phenyl)-2H-tetrazole, (L1)

To a solution of 4-(trifluoromethyl)benzonitrile (1.00 g, 5.85 mmol) in DMF (100 mL) was added sodium azide (1.14 g, 17.55 mmol) and ammonium chloride (0.96 g, 17.55 mmol).

The reaction mixture was stirred for 24 h at 120° C. After being cooled to room temperature, the solvent was evaporated under reduced pressure. The residue was extracted with ethyl acetate and washed with brine and dried over MgSO₄, filtered and concentrated under vacuum. Purification was accomplished via silica gel column chromatography using hexane:ethyl acetate (2:1) as an eluent to afford 5-(4-(trifluoromethyl)phenyl)-2H-tetrazole as a pure white solid (0.96 g, 77% yield). ¹H NMR (300 MHz, CDCl₃): δ 16.19 (br s), 8.26-8.23 (d, J=8.1 Hz, 2H), 7.97-7.94 (d, J=8.1 Hz, 2H). ¹³C NMR (75 MHz, CDCl₃) 131.54-130.26 (q, J=31.87 Hz), 128.35, 127.66, 126.36-126.21 (q, J=3.67 Hz), 125.56, 121.95. APPI MS (m/z): calculated for C₈H₅F₃N₄ [M−H+]−, 213.0; found, 212.7.

### Step 2. Preparation of the Ruthenium Complex T134

The corresponding ligand L1 (2 eq.) and (dcbpy)₂RuCl₂ (1 eq.) were refluxed overnight under N₂ in 5:1:1 ethanol:water:N-methylmorpholine. The solvent was then taken off under vacuum and the obtained dark solid was dissolved in water containing excess tetra-butyl ammonium hydroxide (TBAOH) and applied to a preparative C18-column. The compound was purified by a gradient elution with water/methanol 100%:0% to 80%:20%. Concentrating the solvent that contains the major band under reduced pressure and acidifying to pH 4.8 with 0.1 M HNO₃ resulted in a dark precipitate. The solid was filtered to yield a dark crystalline solid, which was dried under vacuum at 60° C. for 24 h. This afforded the dye with one TBA⁺as a counter cation with quantitative yields

T134•TBA: ¹H NMR (300 MHz, MeOD): δ 9.88-9.86 (d, J=5.7 Hz, 2H), 8.91 (d, J=1.2 Hz, 2H), 8.79 (d, J=1.2 Hz, 2H), 8.12-8.10 (dd, J₁=5.7 Hz, J₂=1.5 Hz, 2H),8.01-7.95 (m, 6H), 7.64-7.60 (m, 6H), 3.24-3.18 (m, 8H), 1.69-1.58 (m, 8H), 1.45-1.33 (m, 8H), 1.02-0.97 (t, J=7.2 Hz, 12H). APPI MS (m/z): calculated for C₅₆H₅₉F₆N₁₃O₈Ru [M−H+]−, 1256.2; found, 1256.1.

### EXAMPLE 3

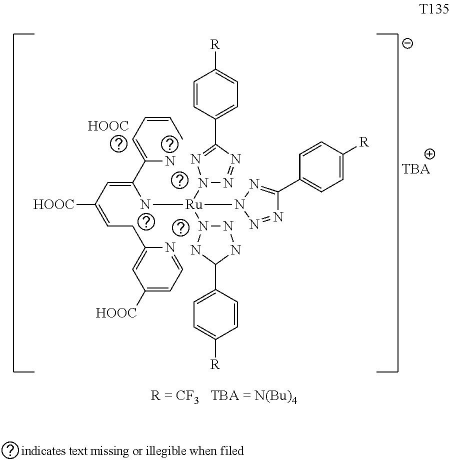

### Ru(L1)₃L4: T135

T135 is one example compound of the M(L1)₃L4 embodiment of the present invention.

### Step 1. Preparation of 5-(4-(trifluoromethyl)phenyl)-2H-tetrazole, (L1)

To a solution of 4-(trifluoromethyl)benzonitrile (1.00 g, 5.85 mmol) in DMF (100 mL) was added sodium azide (1.14 g, 17.55 mmol) and ammonium chloride (0.96 g, 17.55 mmol). The reaction mixture was stirred for 24 h at 120° C. After being cooled to room temperature, the solvent was evaporated under reduced pressure. The residue was extracted with ethyl acetate and washed with brine and dried over MgSO₄, filtered and concentrated under vacuum. Purification was accomplished via silica gel column chromatography using hexane:ethyl acetate (2:1) as an eluent to afford 5-(4-(trifluoromethyl)phenyl)-2H-tetrazole as a pure white solid (0.96 g, 77% yield). ¹H NMR (300 MHz, CDCl₃): δ 16.19 (br s), 8.26-8.23 (d, J=8.1 Hz, 2H), 7.97-7.94 (d, J=8.1 Hz, 2H). ¹³C NMR (75 MHz, CDCl₃) 131.54-130.26 (q, J=31.87 Hz), 128.35, 127.66, 126.36-126.21 (q, J=3.67 Hz), 125.56, 121.95. APPI MS (m/z): calculated for C₈H₅F₃N₄ [M−H+]−, 213.0; found, 212.7.

### Step 2. Preparation of the Ruthenium Complexes T135

The corresponding ligand L1 (6 eq., excess) and (4,4′,4″-trimethoxycarbonyl-2,2′:6′,2″-terpyridine)RuCl₃ (1 eq.) were refluxed overnight under N₂ in 5:1:1 ethanol:water:N-methylmorpholine. The solvent was then taken off under vacuum and the obtained dark solid was dissolved in water containing excess tetra-butyl ammonium hydroxide (TBAOH) and applied to a preparative C18-column. The compound was purified by a gradient elution with water/methanol 100%:0% to 80%:20%. Concentrating the solvent that contains the major band under reduced pressure and acidifying to pH 4.8 with 0.1 M HNO₃ resulted in a dark precipitate. The solid was filtered to yield a dark crystalline solid, which was dried under vacuum at 60° C. for 24 h. This afforded the two dyes with two TBA⁺ as counter cations with quantitative yields.

T135•2TBA: ¹H NMR (300 MHz, MeOD) δ 10.34-10.32 (d, J=5.7 Hz, 2H), 8.90 (s, 4H), 8.45-8.42 (d, J=8.1 Hz, 2H), 8.18-8.15 (d, J=5.7 Hz, 2H), 7.82-7.79 (d, J=8.1 Hz, 2H), 7.76-7.73 (d, J=8.1 Hz, 4H), 7.54-7.51 (d, J=8.1 Hz, 4H), 3.21-3.15 (m, 16H), 1.61-1.56 (m, 16H), 1.38-1.31 (m, 16H), 1.01-0.97 (t, J=7.2 Hz, 24H). APPI MS (m/z): calculated for C₇₄H₉₄F₉N₁₇O₆Ru [M−H+]−, 1588.7; found, 1587.4.

### EXAMPLE 4

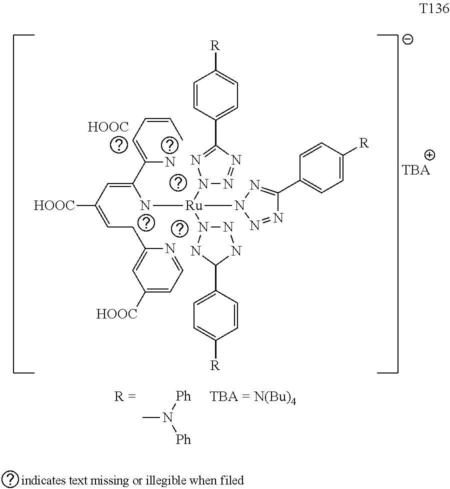

### Ru(L1)₃L4: T136

T136 is another example compound of the M(L1)₃L4 embodiment of the present invention.

### Step 1. Preparation of N,N-diphenyl-4-(2H-tetrazol-5-yl)benzenamine, (L2)

To a solution of 4-(diphenylamino)benzonitrile (1.00 g, 3.70 mmol) in DMF (100 mL) was added sodium azide (0.72 g, 11.11 mmol) and ammonium chloride (0.61 g, 11.11 mmol). The reaction mixture was stirred for 24 h at 120° C. After being cooled to room temperature, the solvent was evaporated under reduced pressure. The residue was extracted with water and ethyl acetate (30 ml×3). The organic layer was washed with brine, dried over MgSO₄, filtered and concentrated under vacuum. Purification was accomplished via silica gel column chromatography using hexane:ethyl acetate (2:1) as an eluent to afford N,N-diphenyl-4-(2H-tetrazol-5-yl)benzenamine as a pure solid (0.78 g, 68% yield). ¹H NMR (300 MHz, CDCl₃): δ 7.89-7.86 (d, J=8.4 Hz, 2H), 7.34-7.26 (m, 4H), 7.16-7.09 (m, 8H). ¹³C NMR (75 MHz, CDCl₃) 150.85, 146.61, 129.61, 128.30, 125.64, 125.15, 124.38, 121.38, 115.64. APPI MS (m/z): calculated for C₁₉H₁₄N₅ [M−H+]−, 312.1; found, 311.9.

### Step 2. Preparation of the Ruthenium Complex T136

The corresponding ligand L2 (6 eq., excess) and (4,4′,4″-trimethoxycarbonyl-2,2′:6′,2″-terpyridine)RuCl₃ (1 eq.) were refluxed overnight under N₂ in 5:1:1 ethanol:water:N-methylmorpholine. The solvent was then taken off under vacuum and the obtained dark solid was dissolved in water containing excess tetra-butyl ammonium hydroxide (TBAOH) and applied to a preparative C18-column. The compound was purified by a gradient elution with water/methanol 100%:0% to 80%:20%. Concentrating the solvent that contains the major band under reduced pressure and acidifying to pH 4.8 with 0.1 M HNO₃ resulted in a dark precipitate. The solid was filtered to yield a dark crystalline solid, which was dried under vacuum at 60° C. for 24 h. This afforded the two dyes with two TBA^{|} as counter cations with quantitative yields.

T136•2TBA: ¹H NMR (300 MHz, MeOD) δ 9.95-9.93 (d, J=5.7 Hz, 2H), 8.79-8.77 (m, 4H), 8.08-8.01 (m, 4H), 7.40-7.37 (d, J=8.7 Hz, 4H), 7.31-7.18 (m, 9H), 7.10-6.92 (m, 14H), 6.81-6.78 (d, J=8.7 Hz, 4H), 3.21-3.15 (m, 16H), 1.61-1.56 (m, 16H), 1.38-1.31 (m, 16H), 1.01-0.97 (t, J=7.2 Hz, 24H). APPI MS (m/z): calculated for C₁₀₇H₁₂₄N₂₀O₆Ru [M−H+]−, 1886.3; found, 1886.4.

### EXAMPLE 5

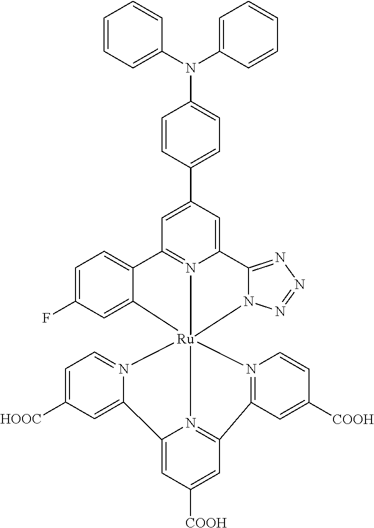

### RuL4L5: T120

T120 is one example compound of the ML4L5 embodiment of the present invention.

Step 1. To a solution of 4-(N,N-diphenylamino)benzaldehyde (10.44 g, 28 mmol) in ethanol (100 ml) was added 1,1-dimethoxypropan-2-one (5.90 g, 50 mmol) followed by piperidine (5.50 g, 50 mmol). The mixture was then heated to reflux for 48 h. After cooling, the solvent was removed in vacuo and the residue was extracted with chloroform (3×100 ml), dried over magnesium sulfate and the solvent was evaporated under reduced pressure. Purification was accomplished via silica gel column chromatography using hexane:ethyl acetate (5%) as the eluent to yield I as a pure yellow solid (90% yield). ¹H NMR (300 MHz, CDCl₃): δ=7.78-7.72 (d, J=15.9 Hz, 1H), 7.46-7.43 (d, J=8.7 Hz, 2H), 7.33-7.26 (m, 5H), 7.14-7.11 (m, 6H), 7.00-6.98 (d, J=8.7, 2H), 6.95-6.89 (d, J=15.8 Hz, 1H), 4.76 (s, 1H), 3.44 (s, 6H). ¹³C NMR (75 MHz, CDCl₃): δ=193.71, 150.46, 146.71, 144.96, 130.03, 129.41, 127.26, 125.57, 124.25, 121.26, 117.93, 103.60, 54.27. APPI MS (m/z): calculated for C₂₄H₂₄NO₃ [M+H]⁻, 374.2; found, 374.0.

Step 2. Reflux a mixture of I (1.15 g, 3.1 mmol), 1-(2-oxo-2-(4-(trifluoromethyl)phenyl)ethyl)pyridinium iodide (1.21 g, 3.10 mmol) and ammonium acetate (2.5 g, excess) in ethanol (40 ml) for 24 h. After cooling to room temperature, the solvent was evaporated under vacuo. The residue was extracted with chloroform (3×100 ml), dried over magnesium sulfate and the solvent was evaporated under reduced pressure. Without any further purification, the crude product was added to a mixture of CHCl₃ (15 mL), acetone (15 mL), distilled water (3.5 mL) and concentrated HCl (1.5 mL). The mixture was heated to reflux for 12 h. The resulting red solution was cooled to room temperature, extracted with chloroform (3×100 ml), dried over magnesium sulfate and the solvent was evaporated under reduced pressure. Purification was accomplished via silica gel column chromatography using hexane:ethyl acetate (10%) as eluent to yield II as pure yellow solid (70% yield). ¹H NMR (300 MHz, CDCl₃): δ=10.21 (s, 1H), 8.26-8.24 (d, J=8.1 Hz, 2H), 8.15-8.13 (m, 2H), 7.80-7.78 (d, J=8.1 Hz, 2H), 7.65-7.60 (m, 2H), 7.35-7.29 (m, 4H), 7.18-7.08 (m, 8H). ¹³C NMR (75 MHz, CDCl₃): δ=193.73, 156.85, 153.25, 150.37, 149.74, 146.96, 141.62, 131.66, 131.23, 129.55, 129.39, 127.90, 127.50, 125.93, 125.28, 124.02, 122.44, 121.79, 117.76. APPI MS (m/z): calculated for C₃₁H₂₁F₃N₂O [M+H]⁺, 495.2; found, 495.0.

Step 3. A mixture of II (0.7 g, 1.4 mmol) and hydroxylamine hydrochloride (0.1 g, 1.4 mmol) was dissolved in ethanol (50 mL). The mixture was heated at reflux for 2 h. After cooling, the solvent was evaporated under vacuo. The residue was extracted with chloroform (3×100 ml), dried over magnesium sulfate and the solvent was evaporated under reduced pressure to yield the crude oxime. Without any further purification, the oxime was dissolved in CH₂Cl₂ (10 mL) to form solution 1. In another round bottom flask (100 mL) CH₂Cl₂ solution of Ph₃P (0.34 g, 1.3 mmol) was treated with trifluoroacetic anhydride (0.31 g, 1.5 mmol) to form solution 2. Solution 2 was stirred for 10 min followed by the addition of solution 1 and triethylamine (0.16 g, 1.5 mmol). The mixture was stirred for 10 min. After that, the mixture was diluted with CH₂Cl₂ (20 ml) and washed with H₂O (30 mL) and brine (20 mL). The organic layer was dried over magnesium sulfate and the solvent was evaporated under reduced pressure. Purification was accomplished via silica gel column chromatography using hexane:dichloromethane (30%) as eluent to afford III as a pure yellow solid (83% yield). ¹H NMR (300 MHz, CDCl₃): δ=8.19-8.17 (d, J=8.1 Hz, 2H), 8.09-8.08 (d, J=1.8 Hz, 1H), 7.84-7.83 (d, J=1.8 Hz, 1H), 7.78-7.75 (d, J=8.4 Hz, 2H), 7.57-7.52 (m, 2H), 7.35-7.29 (m, 4H), 7.18-7.10 (m, 8H). ¹³C NMR (75 MHz, CDCl₃): δ=157.76, 150.37, 150.12, 146.78, 140.87, 134.47, 129.60, 128.09, 127.78, 127.48, 125.93, 125.88, 125.83, 125.44, 124.68, 124.25, 122.16, 120.65, 117.51. APPI MS (m/z): calculated for C₃₁H₂₁F₃N₃ [M+H]⁺, 492.2; found, 492.2.

Step 4. Preparation of L5.

To a solution of 4-(4-(diphenylamino)phenyl)-6-(4-(trifluoromethyl)phenyl)picolinonitrile, compound III, (0.5 g, 1.0 mmol) in DMF (100 mL) was added sodium azide (0.1 g, 1.5 mmol) and ammonium chloride (0.08 g, 1.5 mmol). The reaction mixture was stirred for 3 h at 120° C. After being cooled to room temperature, the reaction mixture was then poured into water and extracted with ethyl acetate (30 ml×3). The organic layer was washed with brine, dried over MgSO₄, filtered and concentrated in vacuo. Purification was accomplished via silica gel column chromatography using hexane:ethyl acetate (20%) as eluent to afford 4-(2-(1H-tetrazol-5-yl)-6-(4-(trifluoromethyl)phenyl)pyridin-4-yl)-N,N-diphenylbenzenamine (L5) as a pure yellow solid (85% yield). ¹H NMR (300 MHz, CDCl₃): δ 8.55-8.54 (d, 1H, J=1.5 Hz), 8.23-8.21 (d, 2H, J=8.1 Hz), 8.05-8.03 (m, 2H), 7.77-7.74 (d, 2H, J=8.4 Hz), 7.67-7.64 (d, 2H, J=9 Hz),7.35-7.30 (m, 2H), 7.19-7,10 (m, 8H). ¹³C NMR (75 MHz, CDCl₃): δ 162.89, 156.87, 155.04, 149.82, 146.94, 144.17, 141.78, 129.55, 129.14, 127.88, 127.54, 125.80, 125.75, 125.32, 124.04, 122.35, 119.91, 119.19. MS (m/z): calculated for C₃₁H₂₀F₃N₆ [M−H⁻], 533.2; found, 533.2.

Step 5. Preparation of the Ruthenium Complexes T120.

A mixture of L5 (1 eq.), (4,4′,4″-trimethoxycarbonyl-2,2′:6′,2″-terpyridine)RuCl₃ (1 eq.) and KOAc (5 eq.) in 30 mL of p-xylene was refluxed overnight under N₂. The solvent was taken off under vacuum and the crude product was purified by silica gel column chromatography using CH₂Cl₂ as the eluent. The resulting solid upon evaporation of the solvent was dissolved in a mixture of THF (10 mL), MeOH (10 mL) and 1.0 M NaOH solution (1.0 mL). The mixture was heated to 60° C. under N₂ for 4 h. The volatiles were removed under vacuum and the residue was dissolved in H₂O and titrated with 2N HCl to pH=3.2 to afford a dark precipitate. The product was filtered, washed with water and acetone consecutively to afford T120 as a pure solid (yield 68%). ¹H NMR (300 MHz, CDCl₃): δ 9.27 (s, 2H), 9.03 (s, 2H), 8,64 (s, 1H), 8.53 (s, 1H), 8.22-8.14 (m, 3H), 7.60 (s, 4H), 7.45-7.40 (m, 5H), 7.23-7.16 (m, 7H), 6.97-6.95 (d, 1H, J=7.8 Hz), 5.75 (s, 1H). MS (m/z): calculated for C₄₉H₂₉F₆N₉O₆Ru [M−H⁺], 998.1; found, 998.6.

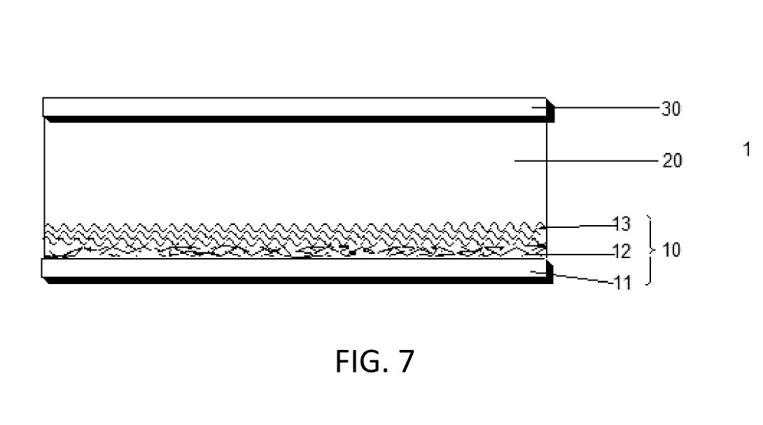

Referring to FIG. 7, a DSSC of an embodiment of the invention comprises an anode 10, an electrolyte 20, and a cathode 30. The anode is comprised of a conducting substrate 11, a semiconducting element 12, and the inventive photosensitizing dye 13. The conducting substrate 11 is conventionally transparent and coated on the outer surface. For example, the conducting substrate 11 may be a coated transparent glass. The transparent glass may be coated with, but is not limited to, the following: indium tin oxide (ITO) or fluorine doped tin dioxide. In other embodiments the conducting substrate 11 is not glass, for example, the conducting substrate 11 may be a titanium sheet, polyethylene naphthalate (PEN), or polyethylene terephthalate (PET).

The inner surface is covered with a semiconducting element 12. The semiconducting element 12 is typically a porous structure to maximize surface area for the photosensitizing dye 13 to be bound thereto. The composition of the semiconducting element 12 may include, but is not limited to, the following: SnO₂, ZnO, TiO₂, and combinations thereof. One of ordinary skill in the art necessarily understands that the semiconducting element 12 material may contribute to the overall efficiency of the cell, for example, due to the Fermi level of the material. As such within the scope of the present invention are materials that have the favorable characteristics to serve as efficient semiconducting elements. The semiconducting element 12 may be a nanostructured film of thickness between about 500 nanometers and about 50 microns. More preferably, the thickness of semiconducting element 12 film is between about 1 micron and about 30 microns. Most preferably, the thickness of semiconducting element 12 film is between about 2 microns and about 25 microns.

The photosensitizing dye 13 is bound to the semiconducting element 12 by methods readily known to one skilled in the art. The photosensitizing dye 13 may include any embodiment within the scope of the present invention.

Electrolyte 20 may be liquid based or solid based. For example, liquid based electrolyte 20 may include, but is not limited to, the following: iodine or iodide salt solution (organic or inorganic), a solution of poly-pyridyl cobalt complex (Co II and III complexes), and a solution of organic disulfide and a salt of its sulfide monomer in aqueous or organic based solvents. Solid based electrolytes 20 may include, but is not limited to a hole conductor, for example, Spiro-MeOTAD (LUMTEC, Taiwan). One of ordinary skill in the art necessarily understands that the efficiency of DSSCs is also affected by the redox potential of the electrolyte 20. As such, within the scope of the invention are electrolytes with favorable redox potentials for utilization in DSSCs.

The cathode 30 is conventionally glass coated on the outer surface. For example, the glass may be coated with, but is not limited to, the following: indium tin oxide (ITO) or fluorine doped tin dioxide. In other embodiments the cathode 30 is not glass, for example, the cathode 30 may be a titanium sheet, polyethylene naphthalate (PEN), or polyethylene terephthalate (PET). Regardless if it is coated glass, polymer or a sheet of titanium, the cathode 30 is further coated with an electro-active material for the respective electrolyte system used. For example, a platinum thin film for iodine based electrolyte, Poly(3,4-ethylenedioxythiophene) (PEDOT) for sulfide based material or carbon based material for cobalt based electrolytes.

Optionally the solar cell may be coated with a UV plastic film to decelerate degradation of the inventive dye.

The photosensitizing dye 13 may be any of the aforementioned photosensitizing dyes T120, T133, T134, T135, or T136. DSSCs incorporating the specific dyes listed are examples merely for illustrative purposes and are in no way intended to restrict the scope of the present invention.

TABLE 1

| | J_{sc}, mA · cm⁻² | V_{oc}, mV | FF | η (%)^{a} |
|---|---|---|---|---|
| T120 | 14.6 | 620 | 0.67 | 6.1 |
| T133 | 13.1 | 620 | 0.65 | 5.3 |
| T134 | 12.0 | 620 | 0.67 | 5.0 |
| T135 | 13.0 | 622 | 0.66 | 5.3 |
| T136 | 6.7 | 495 | 0.65 | 2.2 |
| N719 | 14.6 | 637 | 0.67 | 6.2 |

^{a}Measured under 100 mW · cm−2 simulated AM1.5 spectrum with an active area = 0.126 cm2. Electrolyte EL1: 0.6M DMPII, 0.05M Lil, 0.5M TBP, 0.1M GuSCN and 0.03M I2 in MPN

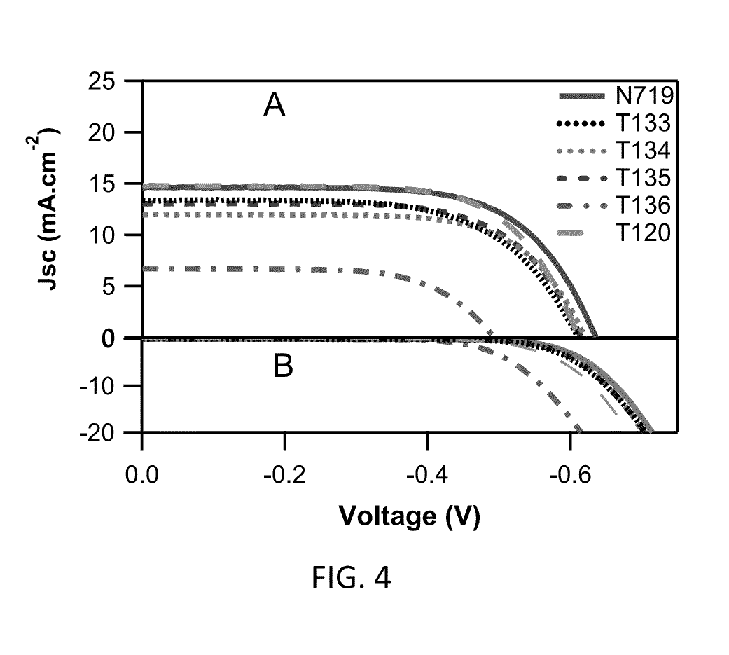

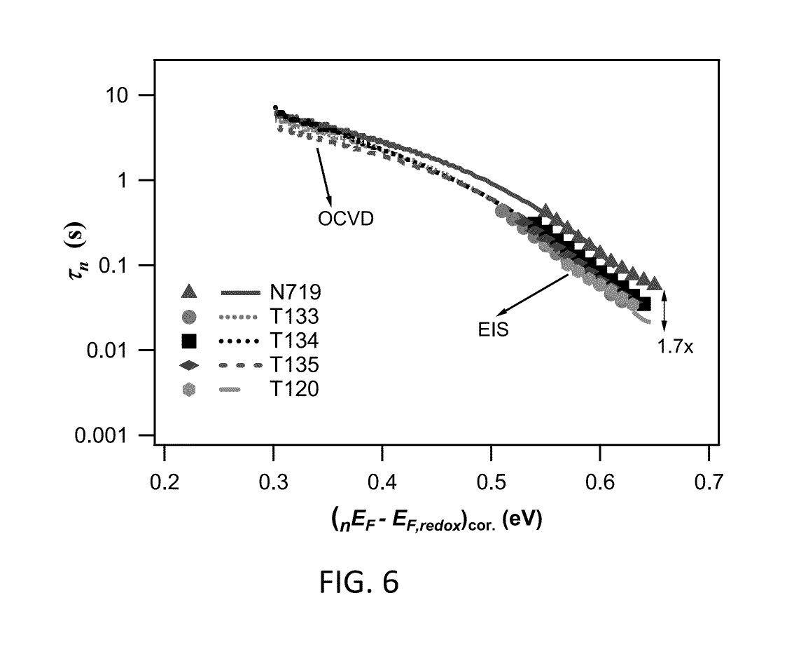

The DSSCs of the present invention incorporate the inventive dyes which lowers the fabrication costs. However, as shown in FIGS. 4-6 and Table 1, the characteristics of the inventive dyes and the overall efficiency of the DSSCs incorporating the dyes illustrate that the lower cost of fabricating the DSSCs do not come at the expense of significant decreases in efficiency.

TABLE 2

| | λ_{abs}, nm | λₑₘ, nm | | E_{1/2}, V | E*₍ₒₓ₎,V |
|---|---|---|---|---|---|
| | (ε, 10⁴ M⁻¹ cm⁻¹)^{a} | (Tₑₘ, ns)^{b} | | vs NHE^{c} | vs NHE |
| T120 | 326 (2.70), 424 (2.26), 520 (14.0), | 814 | (30) | ^{d}1.24, 0.92 | −0.78 |
| | 688 (0.22) | | | | |
| T133 | 311 (4.65), 380 (1.11), 513 (0.93) | 715 | (70) | 1.35, 1.25, 1.10 | −0.81 |
| T134 | 311 (3.75), 380 (1.02), 508 (0.99) | 705 | (85) | 1.20 | −0.74 |
| T135 | 337 (3.77), 385 (1.09), 566 (0.79) | 770 | (120) | 1.00 | −0.78 |
| T136 | 333 (8.63), 388 (1.02), 572 (0.68) | 767 | (140) | 1.35, 1.22, 0.89 | −0.92 |
| N719 | 306 (4.40), 379 (1.40), 525 (1.35) | 755 | (9) | 1.08 | −0.98 |

^{a}Measured in ethanol
^{b}Measured in aerated ethanol with λₑₓ = 532 nm
^{c}measured in DMF with 0.1M TBAPF₆
^{d}measured with an 8 μm TiO₂ film of T120 in 0.1M Bu₄NPF₆ in ACN.

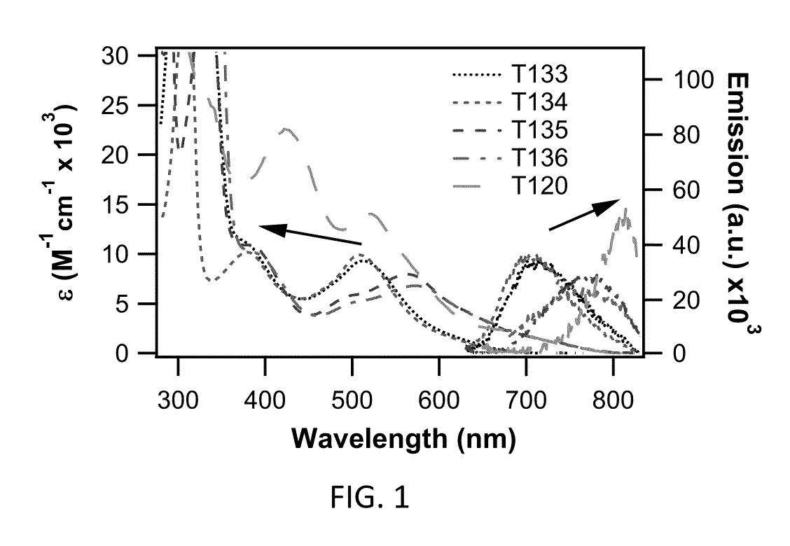

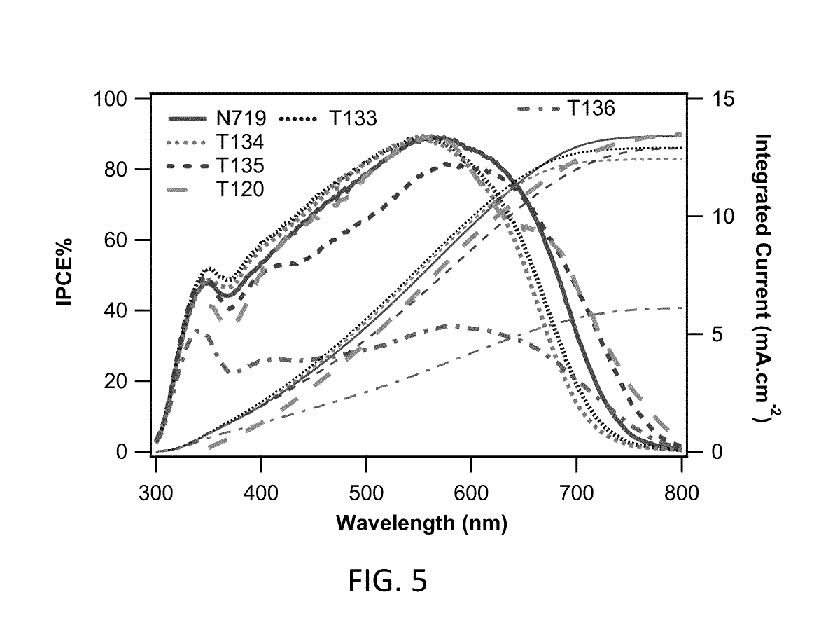

As shown in FIG. 1, some embodiments of the inventive dye show improved absorption at the near IR wavelengths. The DSSCs incorporating the inventive dyes show correspondingly higher efficiencies at the near IR region, as shown in FIG. 5 and Table 2.

While the invention has been described in connection with various embodiments, it will be understood that the invention is capable of further modifications. This application is intended to cover any variations, uses or adaptations of the invention following, in general, the principles of the invention, and including such departures from the present disclosure as, within the known and customary practice within the art to which the invention pertains.

### NON-PATENT LITERATURE

[1] B. O'Regan, M. Gratzel, Nature 1991, 353,737.
[2] A. Yella, H.-W. Lee, H. N. Tsao, C. Yi, A. K. Chandiran, M. K. Nazeeruddin, E. W.-G. Diau, C.-Y. Yeh, S. M. Zakeeruddin, M. Gratzel, Science, 334, 629.
[3] J. Burschka, N. Pellet, S.-J. Moon, R. Humphry-Baker, P. Gao, M. K. Nazeeruddin, M. Gratzel, Nature 2013, 499,316-319.
[4] M. K. Nazeeruddin, F. De Angelis, S. Fantacci, A. Selloni, G. Viscardi, P. Liska, S. Ito, B. Takeru, M. Gratzel, J. Am. Chem. Soc. 2005, 127, 16835.
[5] M. K. Nazeeruddin, P. Pechy, T. Renouard, S. M. Zakeeruddin, R. Humphry-Baker, P. Cornte, P. Liska, L. Cevey, E. Costa, V. Shklover, L. Spiccia, G. B. Deacon, C. A. Bignozzi, M. Gratzel, J. Am. Chem. Soc. 2001, 123,1613.

What is claimed is:

1. A metal complex comprising a formula (1):
M(L1)₂L2L3, (1)
wherein M is a metal selected from a group consisting of metals belonging to groups six through eleven of a long form periodic table;
L₁ is a monodentate ligand comprising a formula (2): 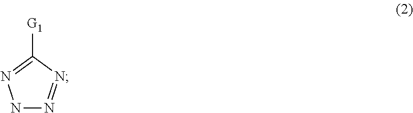
and
L₂ and L₃ are bidentate ligands comprising a formula (3): 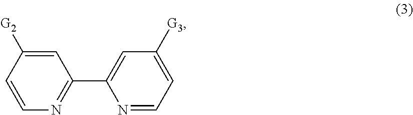
wherein G₁, G₂ and G₃ may duplicate, all be the same, or all be different and are selected from a group consisting of hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

2. The metal complex of claim 1, wherein M is selected from a group consisting of iron, ruthenium, osmium, iridium, cobalt, palladium, platinum, and chromium.

3. The metal complex of claim 1, wherein ligand L₂ is an anchoring group selected from a group consisting of —COOH, —PO₃H₂, —PO₄H₂, —SO₃H, —CONHOH, acetylacetonate, acrylic acid derivatives, malonic acid derivatives, rhodanine-3-acetic acid, propionic acid, deprotonated forms thereof, deprotonated forms of the salts of the deprotonated forms, and chelating groups with it-conducting character.

4. The metal complex of claim 1, wherein G₁, G₂, or G₃ is an anchoring group selected from a group consisting of —COOH, —PO₃H₂, —PO₄H₂, —SO₃H, —CONHOH, acetylacetonate, acrylic acid derivatives, malonic acid derivatives, rhodanine-3-acetic acid, propionic acid, deprotonated forms thereof, deprotonated forms of the salts of the deprotonated forms, and chelating groups with it-conducting character.

5. The metal complex of claim 1, wherein G₁, G₂, and G₃ may duplicate, all be the same, or all be different and is selected from a group consisting of —C₆H₁₃, —CF₃, —CF₂(CF₂)₄CF₃, and structural formulas (a) to (h): 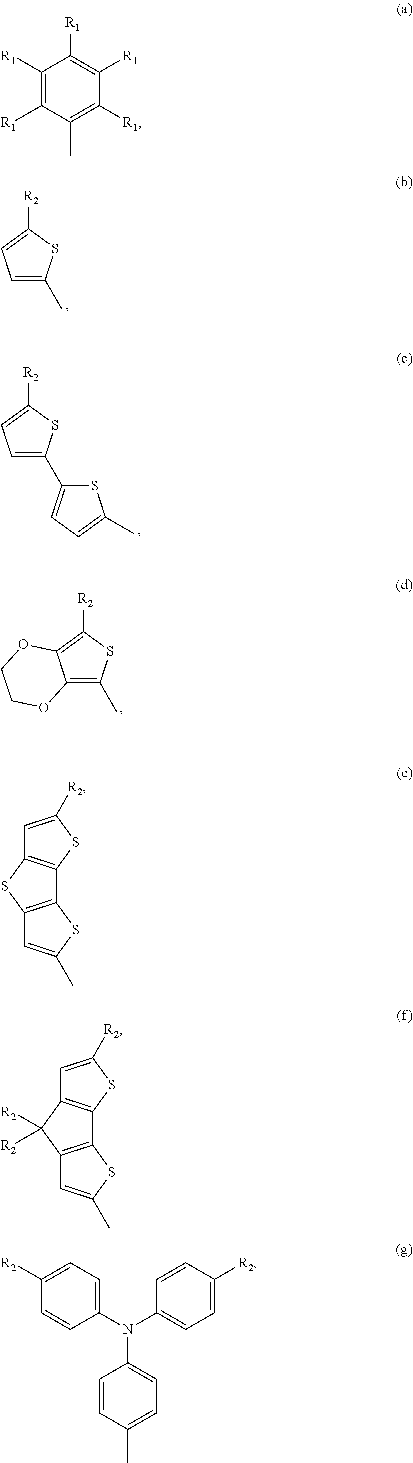 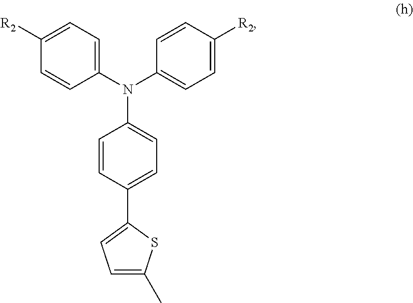
wherein R₁ is selected from a group consisting of hydrogen, halogen, halogenated alkyl groups, preferably —F, —CF₃, —CF₂(CF₂)₄CF₃, alkyl or alkoxy group, in particular butyl, hexyl, octyl, butoxy, hexyloxy, octyl, or octyloxy groups, and R₂ is selected from a group consisting of hydrogen, alkyl, thioalkyl or alkoxy groups, in particular butyl, hexyl, or octyl groups.

6. The metal complex of claim 1, wherein the metal complex is an ammonium or alkali metal salt.

7. The metal complex of claim 1, wherein a semiconducting element loaded with the metal complex is incorporated in a dye sensitized solar cell comprising:
a cathode;
an anode comprising an outer surface, an inner surface, and a conducting substrate covering the outer surface, wherein the semiconducting element loaded with the metal complex covers the inner surface; and
an electrolyte disposed between the semiconducting element and the cathode.

8. A metal complex comprising a formula (4):
M(L1)₃L4 (4),
wherein M is a metal selected from a group consisting of metals belonging to groups six through eleven of a long form periodic table;
L₁ is a monodentate ligand comprising a formula (2): 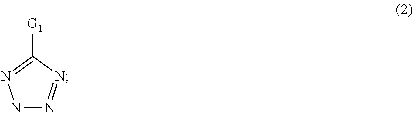
and
L₄ is a tridentate ligand comprising formula (5); 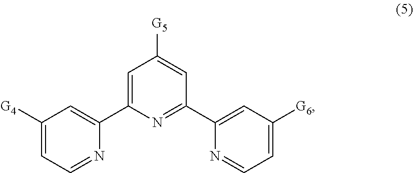
wherein G₁, G₄, G₅ and G₆ may duplicate, triplicate, all be the same, or all be different and are selected from a group consisting of hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

9. The metal complex of claim 8, wherein M is selected from a group consisting of iron, ruthenium, osmium, iridium, cobalt, palladium, platinum, and chromium.

10. The metal complex of claim 8, wherein G₁, G₄, G₅ or G₆ is an anchoring group selected from a group consisting of —COOH, —PO₃H₂, —PO₄H₂, —SO₃H, —CONHOH, acetylacetonate, acrylic acid derivatives, malonic acid derivatives, rhodanine-3-acetic acid, propionic acid, deprotonated forms thereof, deprotonated forms of the salts of the deprotonated forms, and chelating groups with it-conducting character.

11. The metal complex of claim 8, wherein G₁, G₄, G₅, and G₆ may duplicate, triplicate, all be the same, or all be different and is selected from a group consisting of —C₆H₁₃, —CF₃, —CF₂(CF₂)₄CF₃, and structural formulas (a) to (h): 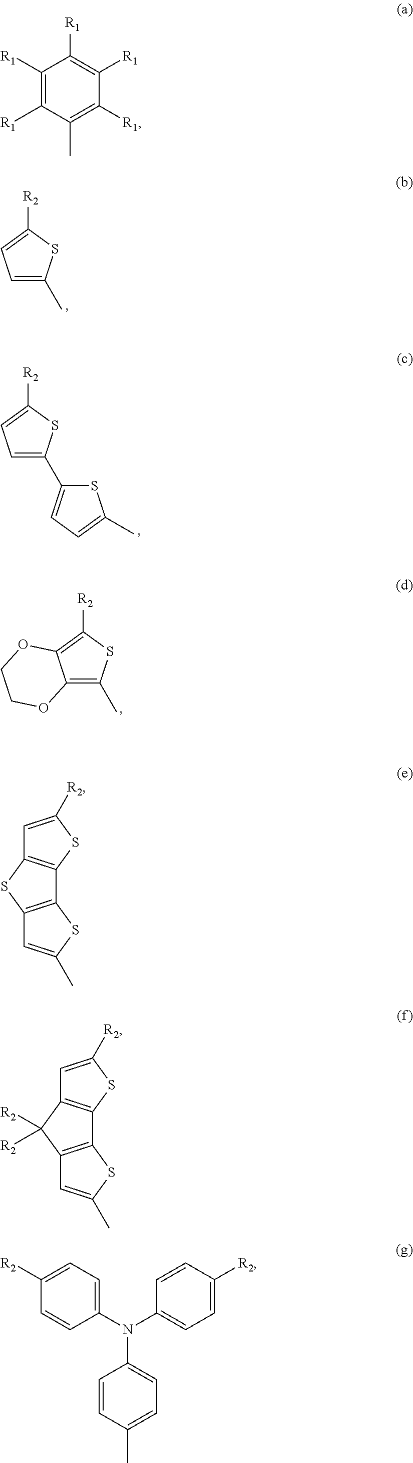 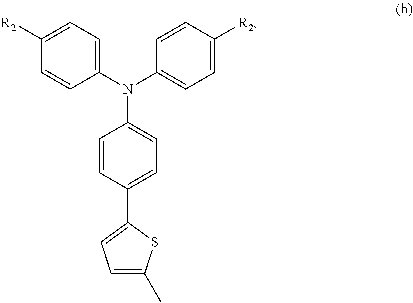
wherein R₁ is selected from a group consisting of hydrogen, halogen, halogenated alkyl groups, preferably —F, —CF₃, —CF₂(CF₂)₄CF₃, alkyl or alkoxy group, in particular butyl, hexyl, octyl, butoxy, hexyloxy, octyl, or octyloxy groups, and R₂ is selected from a group consisting of hydrogen, alkyl, thioalkyl or alkoxy groups, in particular butyl, hexyl, or octyl groups.

12. The metal complex of claim 8, wherein the metal complex is an ammonium or alkali metal salt.

13. The metal complex of claim 8, wherein a semiconducting element loaded with the metal complex is incorporated in a dye sensitized solar cell comprising:
a cathode;
an anode comprising an outer surface, an inner surface, and a conducting substrate covering the outer surface, wherein the semiconducting element loaded with the metal complex covers the inner surface; and
an electrolyte disposed between the semiconducting element and the cathode.

14. A metal complex comprising a formula (6):
ML4L5 (6),
wherein M is a metal selected from a group consisting of metals belonging to groups six through eleven of a long form periodic table;
L₄ is a tridentate ligand comprising formula (5): 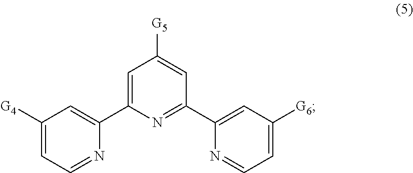
L₅ is a tridentate ligand comprising formula (7): 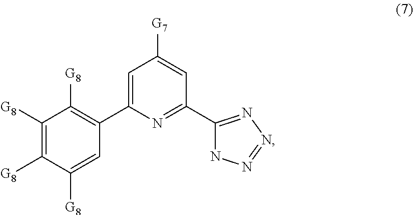
wherein G₄, G₅, G₆, G₇, and G₈ may duplicate, triplicate, quadruplicate, all be the same, or all be different and are selected from a group consisting of hydrogen, halogens, cyano, alkyl groups, halogenated alkyl groups, alkoxy groups, halogenated alkoxy groups, aryl groups, halogenated aryl groups, aryloxy groups, halogenated aryloxy groups, heterocycles, halogenated heterocycles, heterocyclic alkyl groups, halogenated heterocyclic alkyl groups, heterocyclic alkoxy groups, halogenated heterocyclic alkoxy groups, heterocyclic aryl groups, halogenated heterocyclic aryl groups, heterocyclic aryloxy groups, halogenated heterocyclic aryloxy groups, amino groups, halogenated amino groups, aryl amino groups, halogenated aryl amino groups, and anchoring groups.

15. The metal complex of claim 14, wherein M is selected from a group consisting of iron, ruthenium, osmium, iridium, cobalt, palladium, platinum, and chromium.

16. The metal complex of claim 14, wherein G₄, G₅, G₆, G₇, or G₈ is an anchoring group selected from a group consisting of —COOH, —PO₃H₂, —PO₄H₂, —SO₃H, —CONHOH, acetylacetonate, acrylic acid derivatives, malonic acid derivatives, rhodanine-3-acetic acid, propionic acid, deprotonated forms thereof, deprotonated forms of the salts of the deprotonated forms, and chelating groups with it-conducting character.

17. The metal complex of claim 14, wherein G₄, G₅, G₆, G₇, or G₈ may duplicate, triplicate, quadruplicate, all be the same, or all be different and is selected from a group consisting of —C₆H₁₃, —CF₃, —CF₂(CF₂)₄CF₃, and structural formulas (a) to (h): 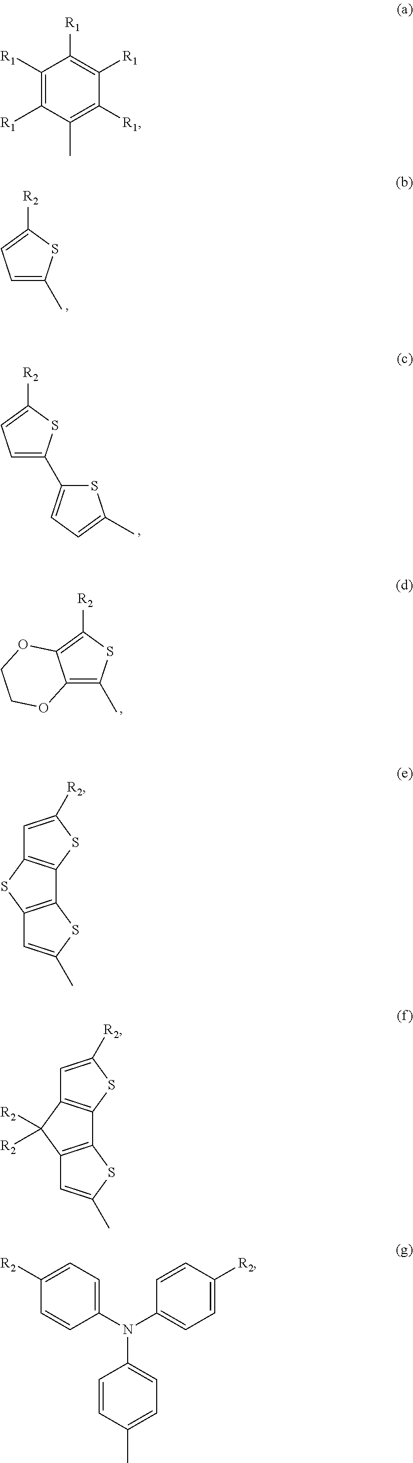 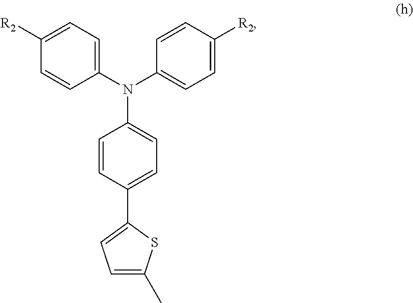
wherein R₁ is selected from a group consisting of hydrogen, halogen, halogenated alkyl groups, preferably —F, —CF₃, —CF₂(CF₂)₄CF₃, alkyl or alkoxy group, in particular butyl, hexyl, octyl, butoxy, hexyloxy, octyl, or octyloxy groups, and R₂ is selected from a group consisting of hydrogen, alkyl, thioalkyl or alkoxy groups, in particular butyl, hexyl, or octyl groups.

18. The metal complex of claim 14, wherein the metal complex is an ammonium or alkali metal salt.

19. The metal complex of claim 14, wherein a semiconducting element loaded with the metal complex is incorporated in a dye sensitized solar cell comprising:
a cathode;
an anode comprising an outer surface, an inner surface, and a conducting substrate covering the outer surface, wherein the semiconducting element loaded with the metal complex covers the inner surface; and
an electrolyte disposed between the semiconducting element and the cathode.
